(19) United States
(12) Patent Application Publication
(10) Pub. No.: US 2025/0183099 A1
(43) Pub. Date: Jun. 5, 2025

(54) ELECTRONIC DEVICE AND METHOD OF MANUFACTURING THE SAME

(71) Applicant: Advanced Semiconductor Engineering, Inc., Kaohsiung (TW)

(72) Inventors: Yi-Hung HOU, Kaohsiung (TW); Yu-Pin TSAI, Kaohsiung (TW); Bo Hua CHEN, Kaohsiung (TW)

(73) Assignee: Advanced Semiconductor Engineering, Inc., Kaohsiung (TW)

(21) Appl. No.: 18/527,170

(22) Filed: Dec. 1, 2023

(51) Int. Cl. H01L 21/78; H01L 23/495; H01L 29/16; H01L 29/417; H01L 29/78

(52) U.S. Cl. CPC H01L 21/78; H01L 23/49513; H01L 23/4952; H01L 23/49524; H01L 23/49565; H10D 30/66; H10D 62/8325; H10D 64/252

(57) ABSTRACT

The present disclosure provides an electronic device and a method of manufacturing the same. The electronic device includes a power die and a patterned layer. The power die has a front surface, a backside surface, and a lateral surface extending between the front surface and the backside surface. The patterned layer is disposed on the backside surface. The patterned layer is indented from the lateral surface of the power die.

### BACKGROUND

### 1. Field of the Disclosure

The present disclosure generally relates to an electronic device, and more particularly to an electronic device including a power die with a backside metal.

### 2. Description of the Related Art

When performing a singulation technique to separate multiple power devices, a dicing technique or a laser ablation technique may be used to cut off a substrate and a conductive layer, functioning as a drain electrode of a power device, formed on the backside surface of the substrate. However, both dicing and laser ablation techniques result in damaging the substrate and/or conductive layer, leading to delamination or failed electrical properties. Therefore, a new electronic device is required.

### SUMMARY

In some embodiments, an electronic device includes a power die and a patterned layer. The power die has a front surface, a backside surface, and a lateral surface extending between the front surface and the backside surface. The patterned layer is disposed on the backside surface. The patterned layer is indented from the lateral surface of the power die.

In some embodiments, an electronic device includes a wafer and a plurality of patterned conductive structures. The wafer has a front surface and a backside surface opposite to the front surface. The plurality of patterned conductive structures is disposed on the backside surface of the wafer and spaced apart from each other.

In some embodiments, a method of manufacturing an electronic device includes: providing a wafer having a plurality of unit dies and a surface exposing a plurality of drain regions of the plurality of unit dies; forming a patterned conductive structure on the plurality of drain regions of the plurality of unit dies to expose a portion of the surface of the carrier.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1A is a cross-sectional view of an electronic device, in accordance with an embodiment of the present disclosure.

FIG. 1B is a partial enlarged view of the electronic device as shown in FIG. 1A, in accordance with an embodiment of the present disclosure.

FIG. 2A is a cross-sectional view of an electronic device, in accordance with an embodiment of the present disclosure.

FIG. 2B is a bottom view of an electronic device, in accordance with an embodiment of the present disclosure.

FIG. 2C is a cross-sectional view of an electronic device, in accordance with an embodiment of the present disclosure.

FIG. 3A is a cross-sectional view of an electronic device, in accordance with an embodiment of the present disclosure.

FIG. 3B is a cross-sectional view of an electronic device, in accordance with an embodiment of the present disclosure.

FIG. 4A is a cross-sectional view of an electronic device, in accordance with an embodiment of the present disclosure.

FIG. 4B is a bottom view of an electronic device, in accordance with an embodiment of the present disclosure.

FIG. 5A, FIG. 5B, and FIG. 5C illustrate one or more stages of an example of a method for manufacturing an electronic device according to some embodiments of the present disclosure.

FIG. 6A, FIG. 6B, and FIG. 6C illustrate one or more stages of an example of a method for manufacturing an electronic device according to some embodiments of the present disclosure.

FIG. 7A, FIG. 7B, FIG. 7C, and FIG. 7D illustrate one or more stages of an example of a method for manufacturing an electronic device according to some embodiments of the present disclosure.

FIG. 8A, FIG. 8B, and FIG. 8C illustrate one or more stages of an example of a method for manufacturing an electronic device according to some embodiments of the present disclosure.

FIG. 9A, FIG. 9B, and FIG. 9C illustrate one or more stages of an example of a method for manufacturing an electronic device according to some embodiments of the present disclosure.

FIG. 10A, FIG. 10B, and FIG. 10C illustrate one or more stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

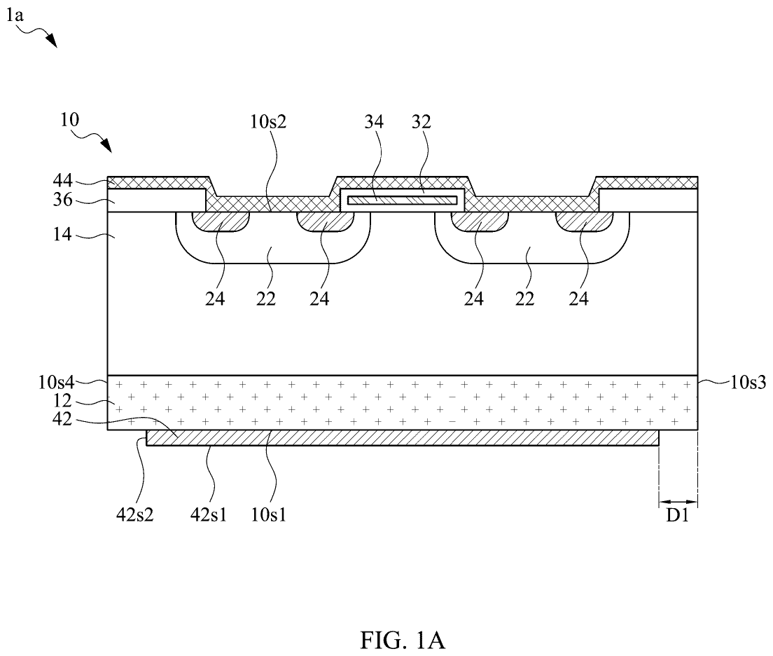

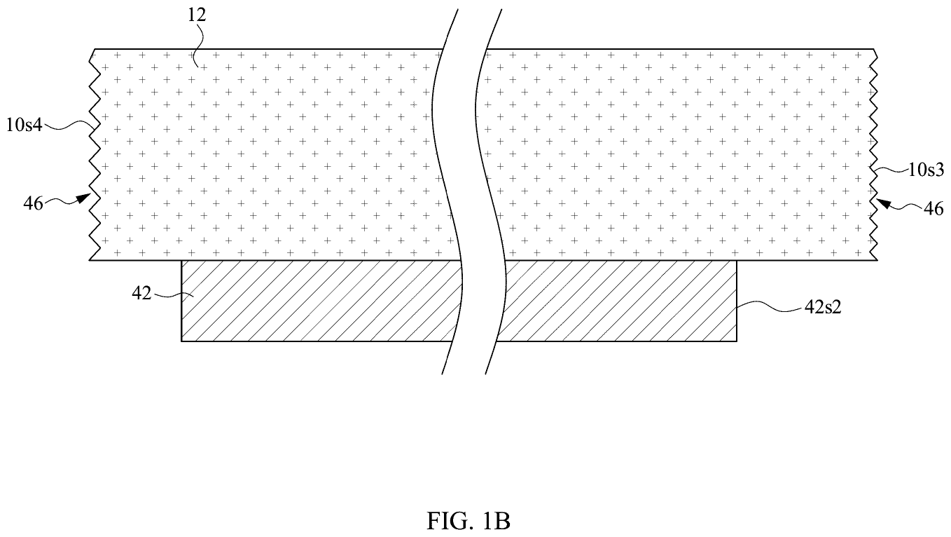

FIG. 1A is a cross-sectional view of an electronic device 1a, in accordance with an embodiment of the present disclosure.

In some embodiments, the electronic device 1a may include an electronic component 10. The electronic component 10 may include a metal insulator semiconductor field effect transistor (MISFET) of a vertical type. The electronic component 10 may be, for example, a power semiconductor device (e.g., a power die or a die) functioning as a power supply switch. The electronic component 10 may have a surface 10s1 (or a backside surface), a surface 10s2 (or a front surface), and a surface 10s3 (or a lateral surface) extending between the surfaces 10s1 and 10s2.

The electronic component 10 may include a semiconductor layer 12 and a semiconductor layer 14, both of which collectively function as a substrate of the electronic component 10. In some embodiments, the semiconductor layer 12 may include a silicon carbide (SiC) monocrystal of a wide bandgap semiconductor. In other embodiments, the semiconductor layer 12 may include a GaN substrate or other suitable semiconductor substrates. In some embodiments, the semiconductor layer 12 may include a first conductive type, such as an n⁺-type. The semiconductor layer 14 may be obtained by epitaxial growth of the semiconductor layer 12. The semiconductor layer 14 may be laminated on an upper surface of the semiconductor layer 12 and may be an SiC semiconductor layer. The semiconductor layer 14 may have the first conductive type, such as an n⁻-type. The semiconductor layer 12 may be arranged as a drain region. The impurity concentration of the semiconductor layer 12 may be equal to or greater than 10¹⁸ cm⁻³ and equal to or less than 10²¹ cm⁻³. The semiconductor layer 14 may be arranged as a drain drift region. The impurity concentration of the semiconductor layer 14 may be equal to or greater than 10¹⁵ cm⁻³ and equal to or less than 10¹⁷ cm⁻³. In some embodiments, the lower surface of the semiconductor layer 12 may be defined as the surface 10s1 of the electronic component 10. The upper surface of the semiconductor layer 14 may be defined as the surface 10s2 of the electronic component 10.

The electronic component 10 may include doped regions 22. The doped region 22 may be located within the semiconductor layer 14. The doped region 22 may function as a body region. The doped region 22 may abut the surface 10s2 of the electronic component 10. The doped region 22 may include a second conductive type, such as a p⁺-type. The impurity concentration of the doped region 22 may be equal to or greater than 10¹⁸ cm⁻³ and equal to or less than 10²¹ cm⁻³.

The electronic component 10 may include doped regions 24. The doped region 24 may function as a source region. The doped region 24 may abut the surface 10s2 of the electronic component 10. The doped region 24 may be embedded within the doped region 22. The doped region 24 may include the first conductive type, such as an n⁺-type. The impurity concentration of the doped region 24 may be equal to or greater than 10¹⁸ cm⁻³ and equal to or less than 10²¹ cm⁻³.

The electronic component 10 may include a gate dielectric 32 and a gate electrode 34. In some embodiments, the gate dielectric 32 may be disposed on or over the surface 10s2 of the electronic component 10. The gate dielectric 32 may include silicon oxide, undoped silicon, silicon nitride, aluminum oxide, aluminum nitride, aluminum oxynitride and/or other suitable materials.

In some embodiments, the gate electrode 34 may be disposed on or over the surface 10s2 of the electronic component 10. The gate electrode 34 may be embedded within the gate dielectric 32. In other embodiments, the gate dielectric 32 and gate electrode 34 may be located within a trench of the semiconductor layer 14 and/or semiconductor layer 12. The gate electrode 34 may be a control electrode of the electronic component 10. The gate electrode 34 may include polysilicon, titanium, nickel, copper, aluminum, silver, gold, tungsten, titanium nitride, and/or other suitable materials.

The electronic component 10 may include a dielectric layer 36. The dielectric layer 36 may be disposed on or over the surface 10s2 of the electronic component 10. The dielectric layer 36 may expose a portion of the surface 10s2 of the electronic component 10. The dielectric layer 36 may expose a portion of the source regions (e.g., doped regions 24) of the electronic component 10. The dielectric layer 36 may include silicon oxide, silicon nitride, and/or other suitable materials.

The electronic device 1a may include a conductive layer 42 (or a backside metal or a patterned layer). In some embodiments, the conductive layer 42 may be disposed on or below the surface 10s1 of the electronic component 10. The conductive layer 42 may function as a drain electrode of the electronic component 10. The conductive layer 42 may be directly in contact with the surface 10s1 of the electronic component 10. The conductive layer 42 may be electrically connected to the drain region (e.g., the semiconductor layer 12) of the electronic component 10. The conductive layer 42 may have a surface 42s1 (or a lower surface) and a surface 42s2 (or a lateral surface). The surface 42s1 of the conductive layer 42 may be configured to connect other devices or substrates (not shown). The conductive layer 42 may include silver (e.g., sintered silver), copper (e.g., sintered copper), titanium, nickel, aluminum, gold, or other suitable materials.

In some embodiments, the conductive layer 42 may be free of a metal joint (or an alloy joint) at the surface 10s1 of the electronic component 10. In some embodiments, the surface 42s2 of the conductive layer 42 is indented or recessed from the surface 10s3 of the electronic component 10. In some embodiments, the surface 42s2 of the conductive layer 42 is noncoplanar within the surface 10s3 of the electronic component 10. That is, the surface 42s2 of the conductive layer 42 and the surface 10s3 of the electronic component 10 may have a non-zero distance therebetween. The surface 42s2 and the surface 10s3 may define a distance D1. In some embodiments, the distance D1 may range between about 1 μm and about 50 μm, such as 1 μm, 5 μm, 10 μm, 20 μm, 30 μm, 40 μm, or 50 μm. In some embodiments, the conductive layer 42 may have a square profile, a rectangular profile, or other suitable profiles in a bottom view.

The electronic device 1a may include a conductive layer 44. In some embodiments, the conductive layer 44 may be disposed on or over the surface 10s2 of the electronic component 10. The conductive layer 44 may be electrically connected to the source regions (e.g., the doped regions 24) of the electronic component 10. The conductive layer 44 may function as a source electrode of the electronic component 10. In some embodiments, a portion of the conductive layer 44 may be free from vertically overlapping the conductive layer 42. In some embodiments, a dimension (e.g., a width) of the conductive layer 44 may be greater than that of the conductive layer 42 in a cross-sectional view.

FIG. 1B is a partial enlarged view of the electronic device 1a as shown in FIG. 1A. In some embodiments, the roughness of the surface 10s3 of the electronic component 10 may be different from the roughness of the surface 42s2 of the conductive layer 42. In some embodiments, the roughness of the surface 10s3 of the electronic component 10 may be greater than the roughness of the surface 42s2 of the conductive layer 42. In some embodiments, the roughness of the surface 10s3 of the electronic component 10 may be different from the roughness of a surface 10s4 (or a lateral surface), opposite to the surface 10s3, of the electronic component 10. In some embodiments, the surface 10s3 of the electronic component 10 may be formed by a singulation process, which may include a non-mechanical process, such as laser cutting, laser ablation, scribing, or other suitable processes. For example, the surface 10s3 of the electronic component 10 may be formed by performing a laser ablation technique (e.g., a laser scribing technique), and the conductive layer 42 may be free of said laser ablation technique, leading to a difference in roughnesses therebetween. In some embodiments, the surface 10s3 of the electronic component 10 may define a recess 46 caused by the laser ablation technique.

In a comparative embodiment, when a singulation technique is performed to separate multiple power dies, a dicing blade may be used to saw a semiconductor layer and a drain electrode, which thereby causes delamination between the semiconductor layer and the drain electrode due to stress and the brittleness of an SiC semiconductor layer. In another comparative embodiment, a laser ablation technique is performed to cut off a semiconductor layer and a drain electrode. In this condition, the power of the laser ablation technique should be relatively high to ensure the drain electrode is cut off. However, such high power may cause thermal debris, which results in a negative effect on electrical properties of the electronic component. In the embodiments as described with respect to FIG. 1A and FIG. 1B, the conductive layer 42 may be patterned before performing a singulation technique. Thus, the conductive layer 42 is free of being cut by a singulation technique. As a result, when a laser ablation technique is performed, the laser source with a relatively small power may be selected to prevent the aforementioned issues.

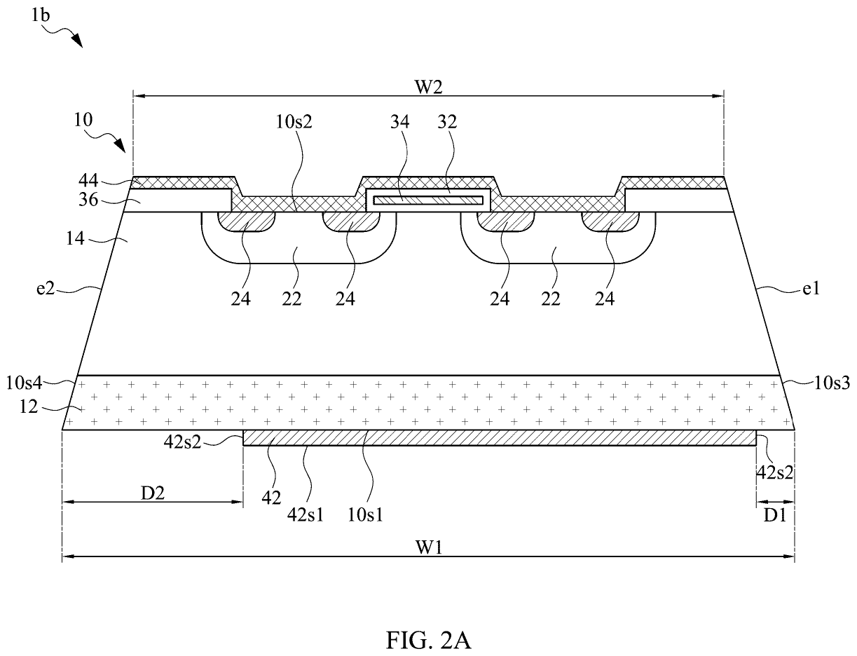

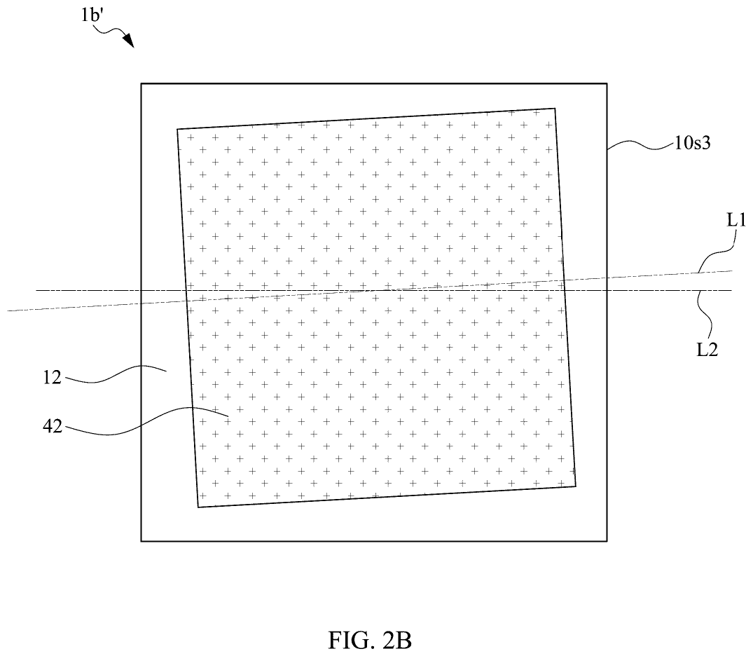

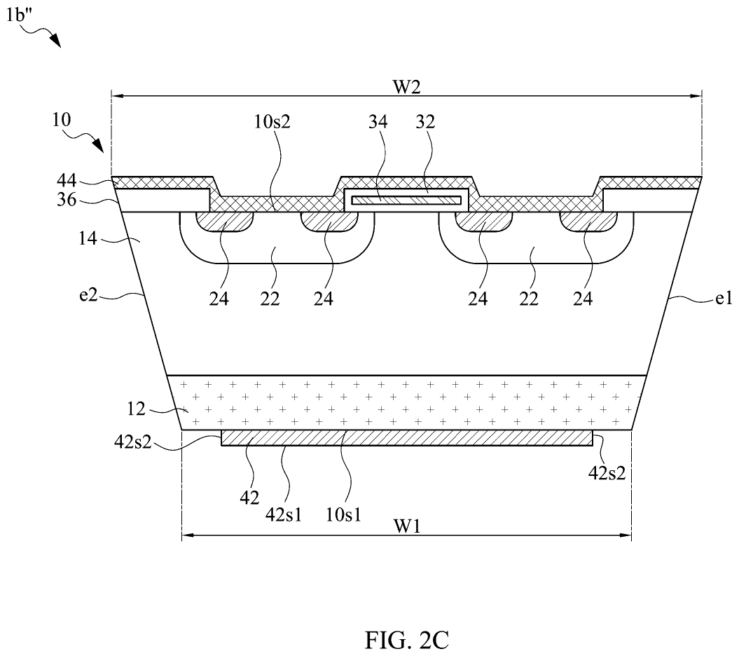

FIG. 2A is a cross-sectional view of an electronic device 1b, in accordance with an embodiment of the present disclosure. The electronic device 1b is similar to the electronic device 1a, with differences therebetween as follows.

In some embodiments, the surface 10s3 of the electronic component 10 may be slanted with respect to the surface 42s2 of the conductive layer 42. That is, the surface 10s3 and the surface 42s2 may be non-parallel. In some embodiments, the surface 10s2 of the electronic component 10 may have a dimension (e.g., width or surface area) greater than the surface 10s1 of the electronic component 10. For example, a width W1 of the surface 10s1 may be greater than a width W2 of the surface 10s2 in a cross-sectional view.

In some embodiments, the distance D1 between the surface 42s2 of the conductive layer 42 and a side e1 (or edge) of the electronic component 10 may be different from a distance D2 between the surface 42s2 of the conductive layer 42 and a side e2 (or edge) of the electronic component 10. In other embodiments, the distance D1 may be substantially the same as the distance D2. In some embodiments, the slope of the side e1 may be different from that of the side e2. For example, the angle defined by the side e1 and the surface 10s1 may be different from that defined by the side e2 and the surface 10s1.

FIG. 2B is a bottom view of an electronic device 1b′, in accordance with an embodiment of the present disclosure. An imaginary line L1 may pass through the geometric center of the conductive layer 42 and may parallel to one side (or long axis or short axis) of the conductive layer 42. An imaginary line L2 may pass through the geometric center of the semiconductor layer 12 and may parallel to one side (or long axis or short axis) of the semiconductor layer 12. In some embodiments, the imaginary line L1 is non-parallel to the imaginary line L2. The imaginary line L1 and the imaginary line L2 may define an angle greater than 0 and less than 90°. That is, the lateral surface of the semiconductor layer 12 of the electronic component 10 is nonparallel to the lateral surface of the conductive layer 42.

FIG. 2C is a cross-sectional view of an electronic device 1b″, in accordance with an embodiment of the present disclosure. In some embodiments, the width W1 of the surface 10s1 may be less than the width W2 of the surface 10s2 in a cross-sectional view.

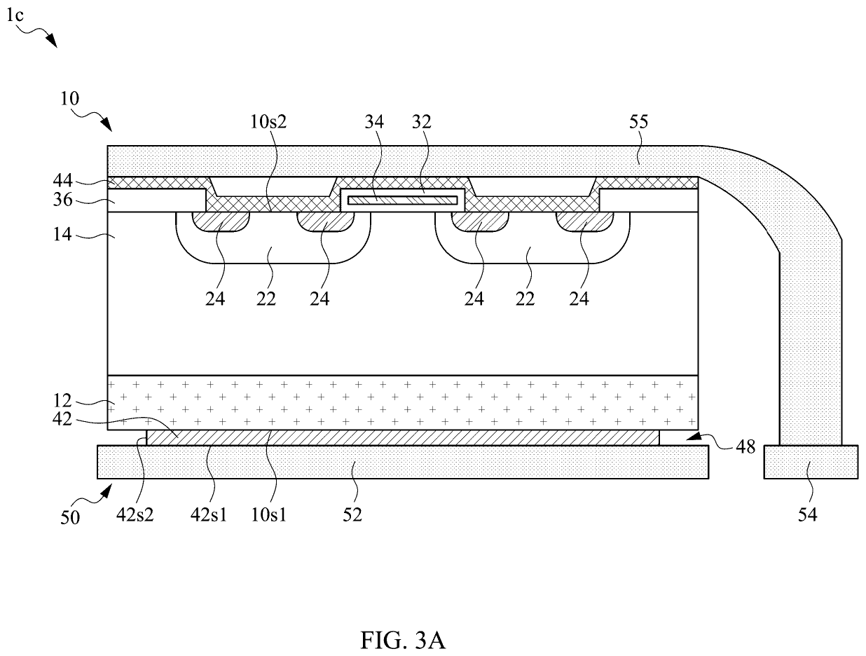

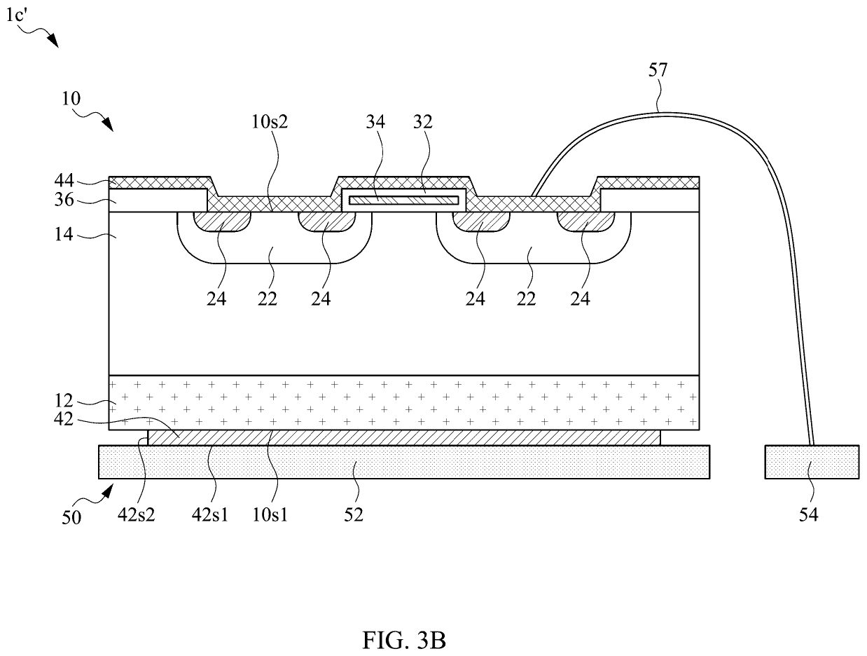

FIG. 3A is a cross-sectional view of an electronic device 1c, in accordance with an embodiment of the present disclosure. The electronic device 1c is similar to the electronic device 1a, with differences therebetween as follows.

In some embodiments, the electronic device 1c may include a carrier 50. The carrier 50 may be electrically connected to the electronic component 10. In some embodiments, the carrier 50 may include a lead frame. The carrier 50 may be made of copper, copper alloy, or another suitable metal or alloy. The carrier 50 may include a die paddle 52 and leads 54. Further, a conductive clip 55 may be disposed on the lead 54.

The die paddle 52 may be disposed on or below the surface 10s1 of the electronic component 10. The die paddle 52 may support the electronic component 10. The die paddle 52 may support the conductive layer 42. The die paddle 52 may be electrically connected to the conductive layer 42. The die paddle 52 may be in contact with the surface 42s1 of the conductive layer 42. In some embodiments, the die paddle 52 and the semiconductor layer 12 may define a gap (or a recess) 48 surrounding the conductive layer 42.

The lead 54 may be spaced apart from the die paddle 52. The conductive clip 55 (or conductive element) may be disposed on or over the surface 10s2 of the electronic component 10. The conductive clip 55 may be electrically connected to the conductive layer 44. By imposing a potential difference between the die paddle 52 and lead 54, a drain current may flow from the conductive layer 42, through the semiconductor layer 12, semiconductor layer 14, and the doped region 24, toward the conductive layer 44 or along an opposite direction.

FIG. 3B is a cross-sectional view of an electronic device 1c′, in accordance with an embodiment of the present disclosure. In some embodiments, the conductive clip 55 as shown in FIG. 3A may be replaced by a conductive wire 57 (or a conductive element). The conductive wire 57 may have a first terminal connected to the lead 54 and a second terminal connected to the conductive layer 44.

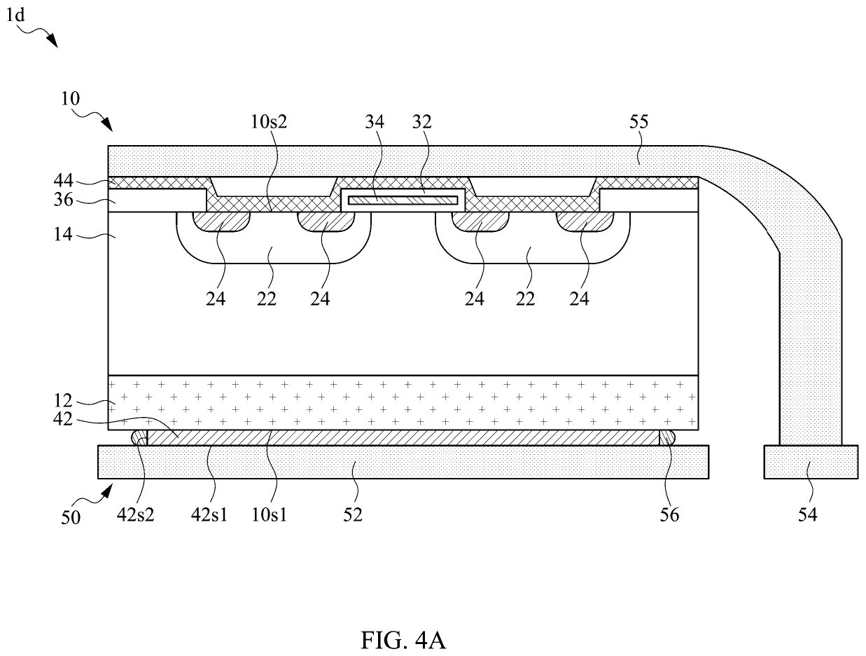

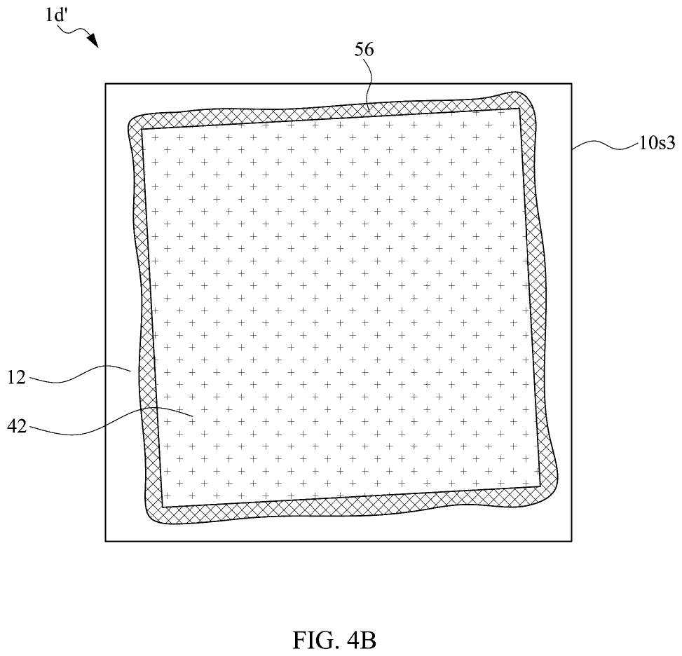

FIG. 4A is a cross-sectional view of an electronic device 1d, in accordance with an embodiment of the present disclosure. The electronic device 1d is similar to the electronic device 1c, with differences therebetween as follows.

In some embodiments, the electronic device 1d may include electrical connectors 56. In some embodiments, the electrical connector 56 may be disposed on the surface 42s2 of the conductive layer 42. In some embodiments, a portion (not shown) of the electrical connector 56 may be disposed between the conductive layer 42 and the die paddle 52. In some embodiments, the electrical connector 56 may be disposed on or below the surface 10s1 of the electronic component 10. The electrical connector 56 may be electrically connected to the carrier 50. The electrical connector 56 may be configured to reduce the impedance between the electronic component 10 and the carrier 50. In some embodiments, the electrical connector 56 may include a solder material(s) or a sintered material. In some embodiments, the electrical connector 56 may include alloys of gold and tin solder or alloys of silver and tin solder, or other suitable materials.

FIG. 4B is a bottom view of an electronic device 1d′, in accordance with an embodiment of the present disclosure. It should be noted that some elements (e.g., die paddle 52) are omitted for brevity. In some embodiments, the electrical connector 56 may be disposed on the four sides of the conductive layer 42 and surround the conductive layer 42. Further, the electrical connector 56 may have a roughness edge from a top view.

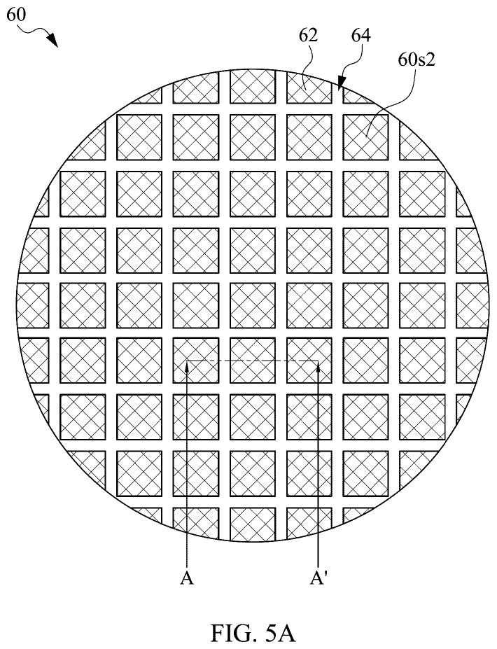

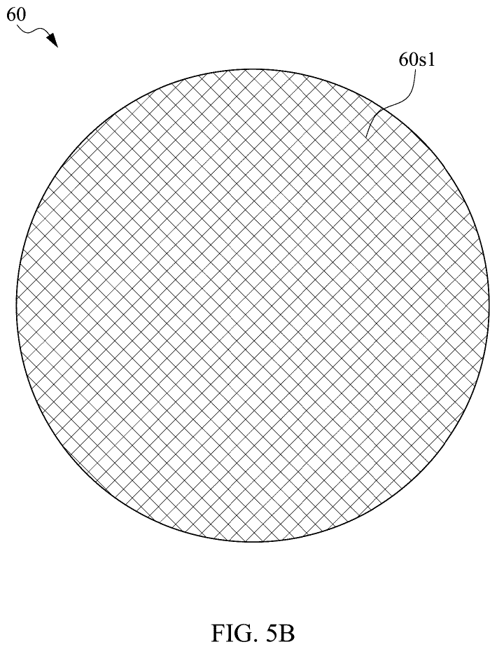

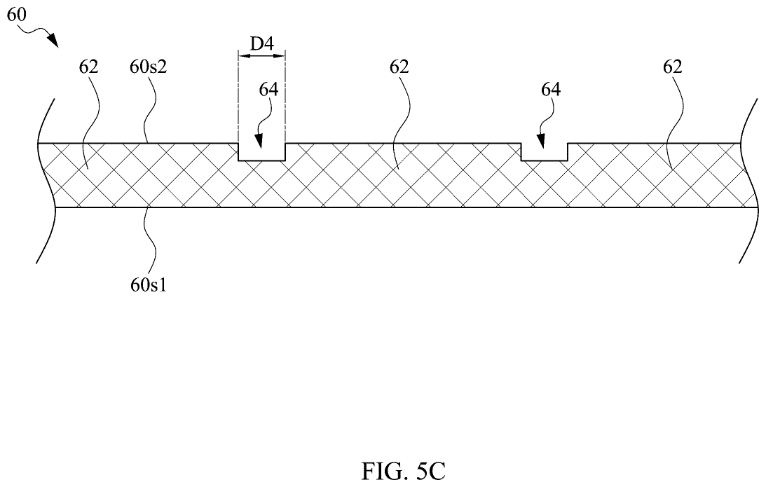

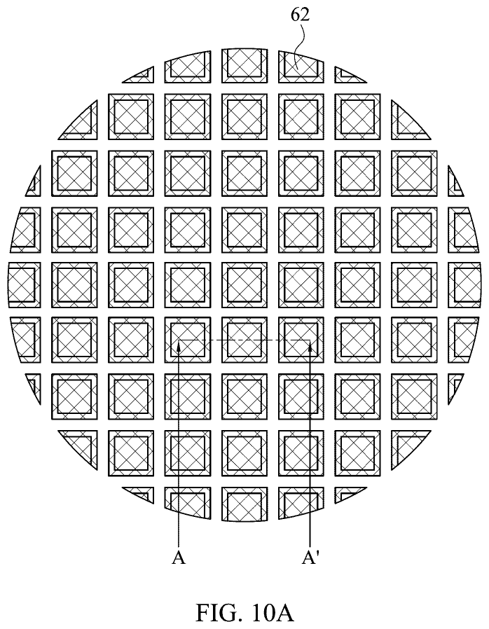

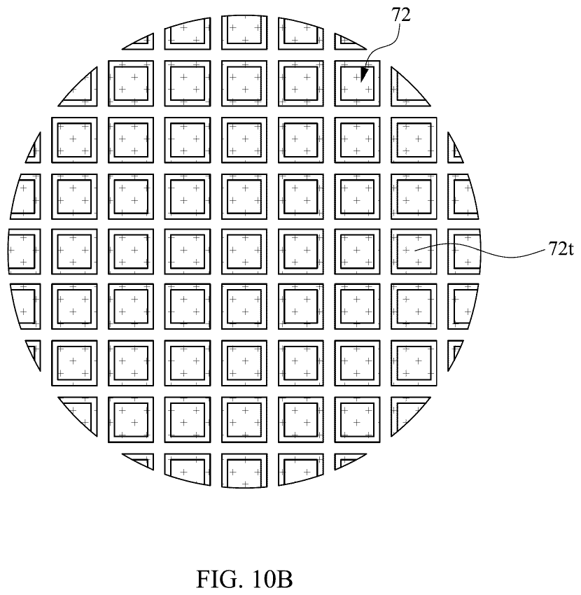

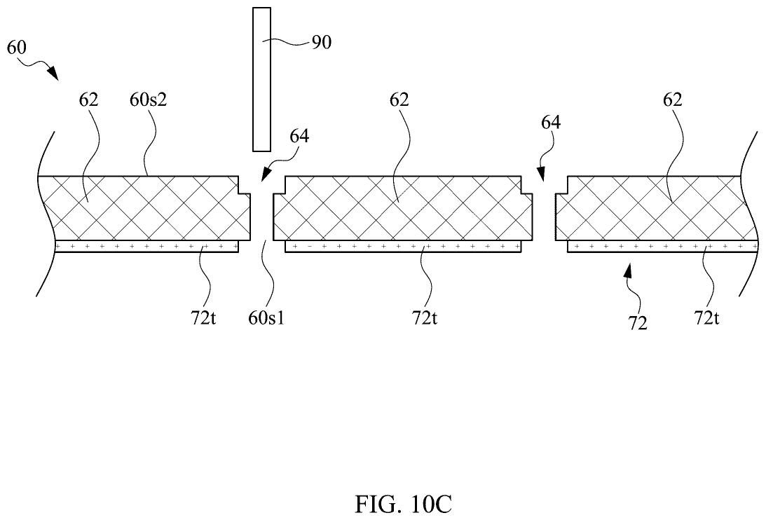

FIGS. 5A-10A, FIGS. 5B-10B, and FIGS. 5C-10C illustrate various stages of an example of a method for manufacturing an electronic device according to some embodiments of the present disclosure, wherein FIGS. 5A-10A are top views, FIGS. 5B-10B are bottom views, and FIGS. 5C-10C are cross-sectional views along line A-A′ of FIG. 5A-10A, respectively. More specifically, FIGS. 5A-10A, FIGS. 5B-10B, and FIGS. 5C-10C illustrate various stages of a wafer-level electronic device which is singulated to produce multiple dies in the stage as shown in FIGS. 10A, 10B, and 10C.

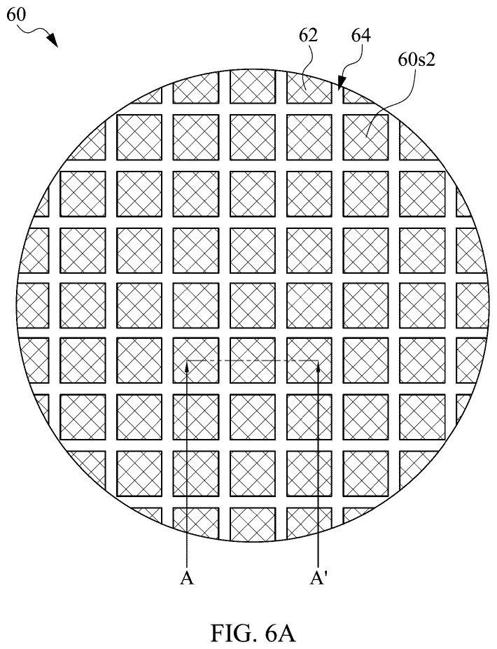

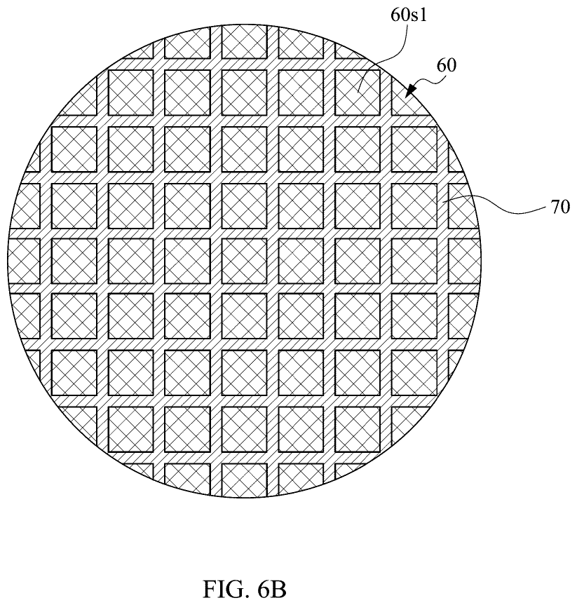

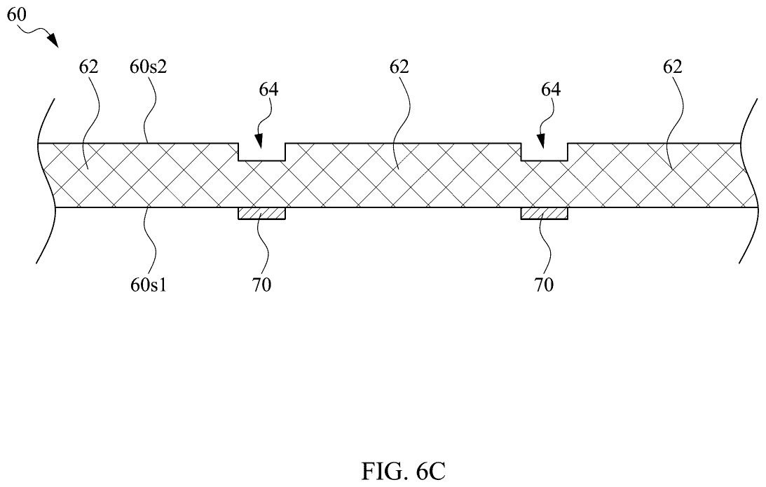

Referring to FIGS. 5A, 5B, and 5C, a wafer 60 (or a carrier) may be provided. The wafer 60 may be, for example, a semiconductor wafer. In some embodiments, the substrate of the wafer 60 may include or be made of silicon carbide. The wafer 60 may have a surface 60s1 (or a backside surface) and a surface 60s2 (or a front surface) opposite to the surface 60s1. The wafer 60 may include a plurality of dies 62. Each of the dies 62 may correspond to a power semiconductor device, such as the electronic component 10 as shown in FIGS. 1A-4. A plurality of scribe lines/streets 64 may be disposed between the dies 62. The scribe line/street 64 may be disposed or defined on the surface 60s2 of the wafer 60. In some embodiments, a dimension D4 (e.g., a length or a width) of the scribe line/street 64, or a distance between neighboring dies 62, may range from about 100 μm to about 200 μm, such as 100 μm, 150 μm, or 200 μm. Although FIG. 6C illustrates that there are recesses at the locations on which the scribe lines/streets 64 are defined, there may be no substantial height differences between the die 62 and the scribe line/street 64 in other embodiments.

Referring to FIGS. 6A, 6B, and 6C, a mask 70 may be disposed on or below the surface 60s1 of the wafer 60. The mask 70 may be configured to define the pattern of drain electrodes. In some embodiments, the profile of the mask 70 may be substantially the same as that of the scribe lines/streets 64. In some embodiments, the dimension (e.g., width or length) of the mask 70 may be the same as that of the scribe line/street 64. For example, the mask 70 may include a plurality of bars forming a mesh-shaped profile. Each of the bars has a width (or length) the same as that of the scribe line/street 64. The mask 70 may cover the surface 60s1 and vertically overlap the scribe line/street 64. In some embodiments, the mask 70 may be vertically aligned with the scribe line/street 64. In some embodiments, the mask 70 may be vertically partially misaligned with the scribe line/street 64.

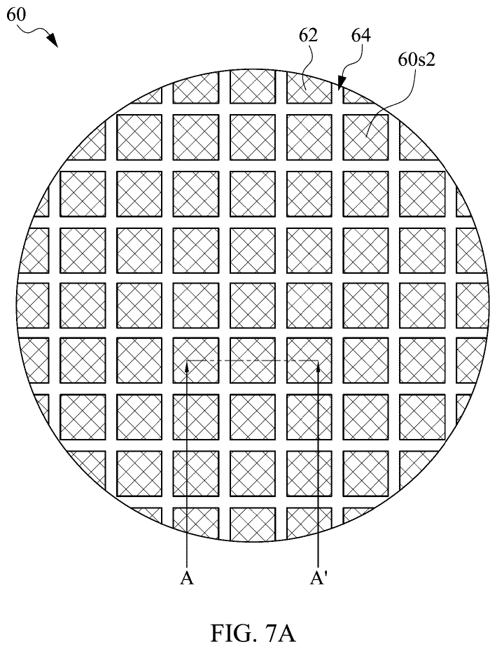

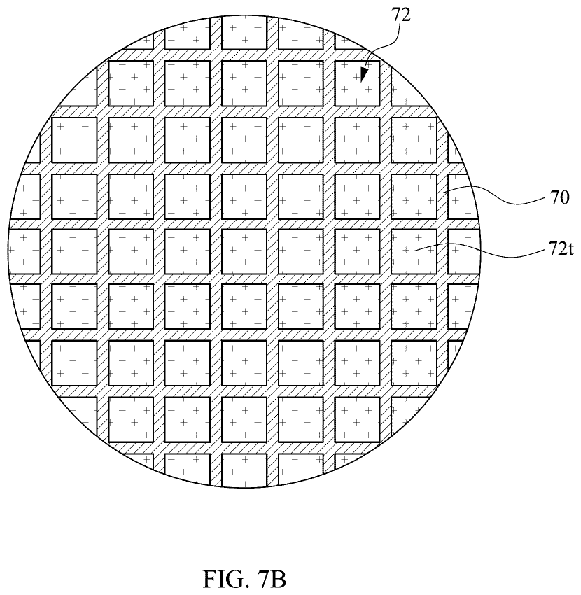

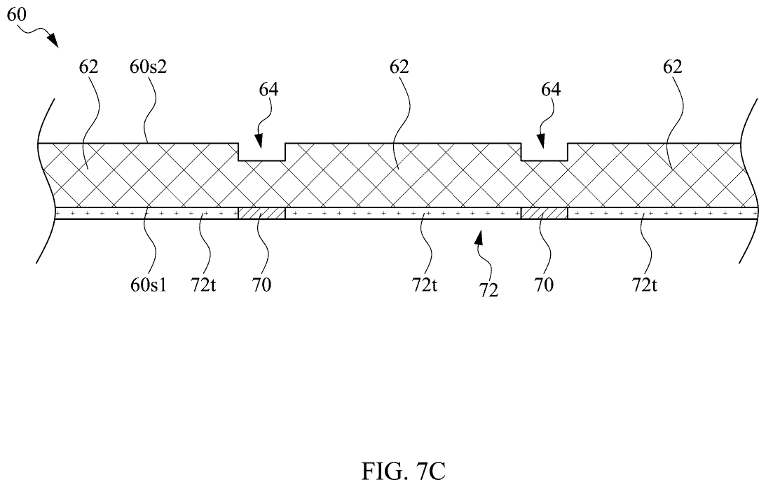

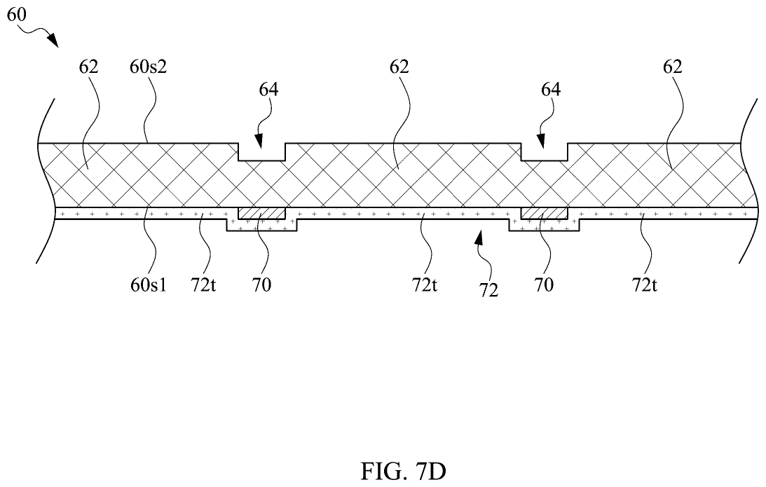

Referring to FIGS. 7A, 7B, and 7C, a patterned conductive layer 72 (or a patterned conductive structure(s) or a conductive layer) may be formed on the surface 60s1 of the wafer 60. In some embodiments, the patterned conductive layer 72 may be formed on the backside surface of the die 62. In some embodiments, the patterned conductive layer 72 is not formed on the region corresponding to the scribe line/street 64. The patterned conductive layer 72 may include a plurality of segments 72t, each of which corresponds to a drain electrode of the die 62. The patterned conductive layer 72 may be formed by, for example, a sputter technique or other suitable techniques.

In other embodiments, as shown in FIG. 7D, the patterned conductive layer 72 may also be formed on or over the mask 70.

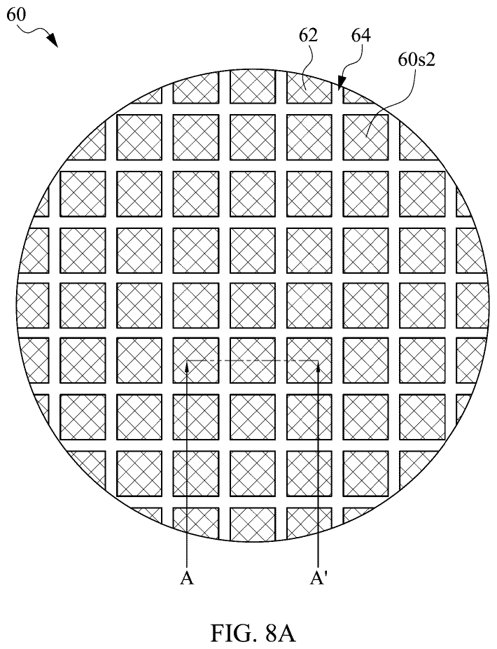

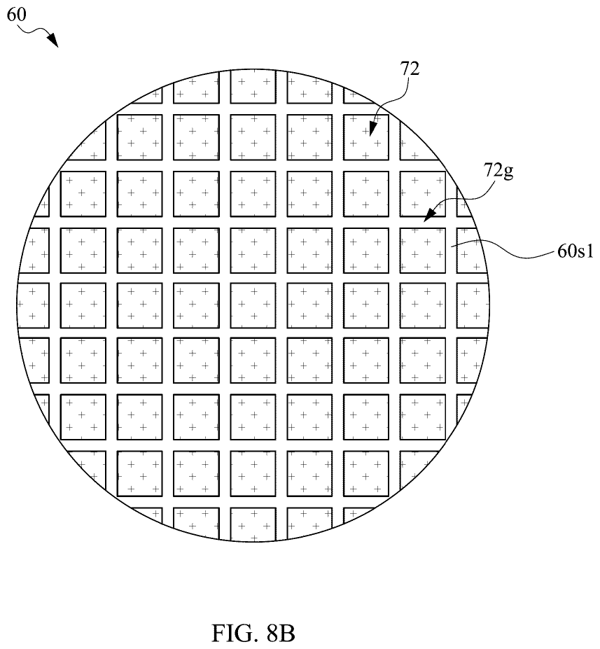

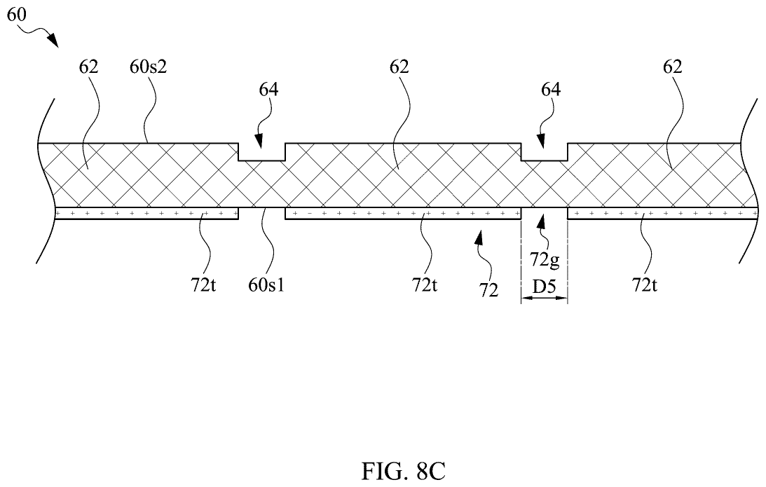

Referring to FIGS. 8A, 8B, and 8C, the mask 70 may be removed to expose a portion of the surface 60s1 of the wafer 60. The patterned conductive layer 72 may define gaps 72g exposing the surface 60s1 of the wafer 60. The location of the gaps 72g of the patterned conductive layer 72 may be vertically aligned with the scribe lines/streets 64. The profile of the patterned conductive layer 72 may be determined by the mask 70 so that the gaps 72g of the patterned conductive layer 72 have a profile and a dimension substantially the same as those of the scribe lines/streets 64. In some embodiments, a dimension D5 (e.g., a length or a width) of the gap 72g of the patterned conductive layer 72 may range from about 100 μm to about 200 μm, such as 100 μm, 150 μm, or 200 μm. Although FIG. 8C illustrates that the gaps 72g of the patterned conductive layer 72 may be perfectly aligned with the scribe line/street 64 along the vertical direction, the gaps 72g of the patterned conductive layer 72 may be partially misaligned with the scribe line/street 64 along the vertical direction in other embodiments. In the embodiments where the patterned conductive layer 72 is formed on or over the mask 70, the portion of patterned conductive layer 72 on the mask 70 may be removed.

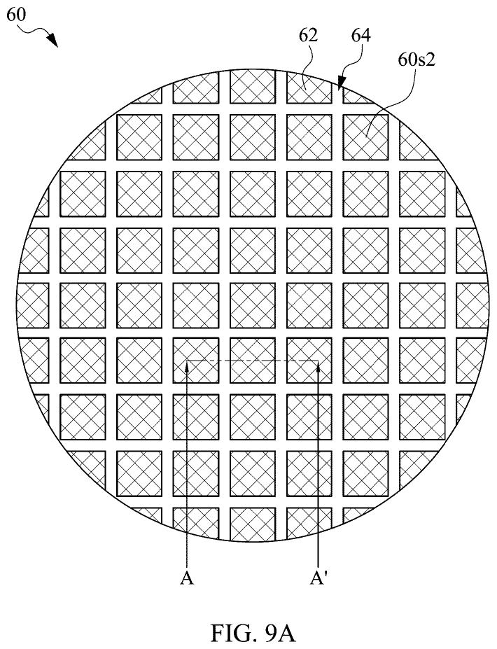

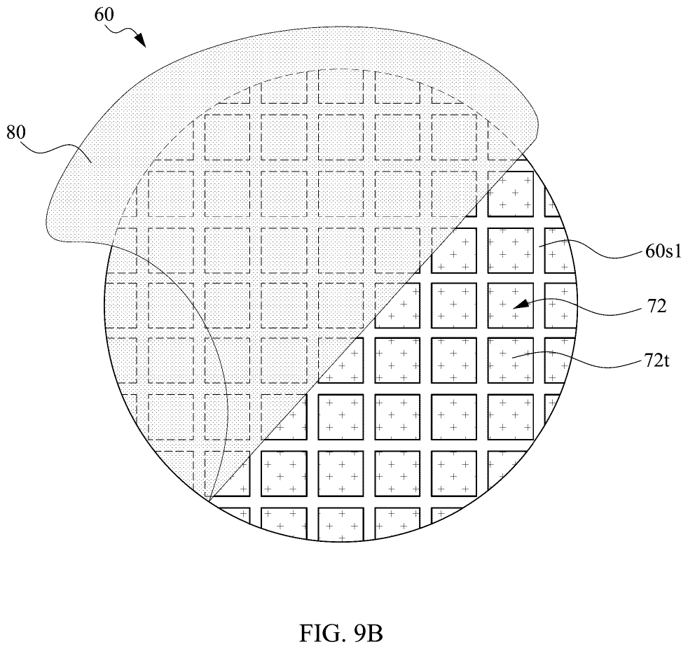

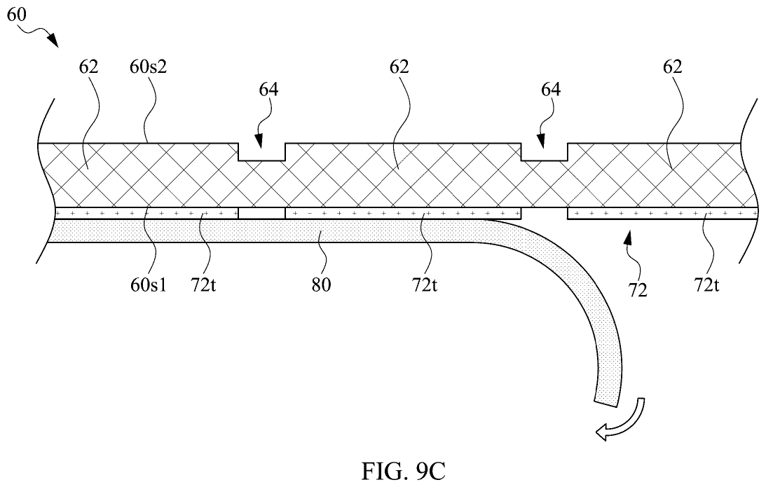

Referring to FIGS. 9A, 9B, and 9C, a peeling test may be performed. The peeling test may be configured to determine whether each of the segments 72t of the patterned conductive layer 72 is delaminated from the wafer 60 (or die 62). In some embodiments, a tape 80 may be attached to the patterned conductive layer 72, and a pulling force may be imposed on the tape 80. After the peeling test is performed, the ratio of good dies (e.g., no delamination occurs between the segment 72t and a corresponding die 62) to bad dies (e.g., delamination occurs between the segment 72t and a corresponding die 62) at this stage may be obtained.

Referring to FIGS. 10A, 10B, and 10C, the dies 62 may be separated. In some embodiments, a laser ablation technique (e.g., a laser scribing technique) may be performed to cut off the wafer 60. A laser 90 may be imposed on the scribe line/street 64 to cut off the wafer 60. Since the patterned conductive layer 72 is not formed on the region of the scribe line/street 64, the patterned conductive layer 72 may be free of being cut off by the laser 90. Accordingly, the laser 90 with a relatively small power may be used to prevent a thermal stress causing negative effects on the dies 62. After the dies 62 are separated, the ratio of good dies (e.g., no delamination occurs between the segment 72t and a corresponding die 62) to bad dies (e.g., delamination occurs between the segment 72t and a corresponding die 62) at this stage may be obtained. By comparing ratios of good dies at stages of FIGS. 9A-9C and FIGS. 10A-10C, the root cause of delamination of the die 62 or delamination between the die 62 and the patterned conductive layer 72 may be determined. For example, if the ratios of good dies at the stage of FIGS. 9A-9C to the stage of FIGS. 10A-10C have no significant difference, the delamination may be attributed to manufacturing processes preceding the formation of the patterned conductive layer 72; if the ratios of good dies at the stage of FIGS. 9A-9C to the stage of FIGS. 10A-10C have a significant difference, the delamination may be attributed to the stage of separating the dies 62. In response to a determined root cause (or good dies ratios between said stages), corresponding process conditions can be modified and/or adjusted. In a comparative example, a conductive layer, functioning as a drain electrode, is formed on the backside surface of a wafer without a patterned profile, and the conductive layer is cut off along with the wafer. In this condition, a peeling test cannot be performed. As a result, the root cause of delamination cannot be determined.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the term “a distance between A and B” may refer to a length from an edge of A to an edge of B or to a length from a center of A to a center of B.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a power die having a front surface, a backside surface, and a lateral surface extending between the front surface and the backside surface; and
a patterned layer disposed on the backside surface, wherein the patterned layer is indented from the lateral surface of the power die.

2. The electronic device of claim 1, wherein the patterned layer comprises a sintered material.

3. The electronic device of claim 1, wherein the power die comprises a source region abutting the front surface and a drain region abutting the backside surface, and the patterned layer is electrically connected to the drain region of the power die.

4. The electronic device of claim 1, wherein a roughness of a lateral surface of the patterned layer is less than a roughness of the lateral surface of the power die.

5. The electronic device of claim 1, wherein a first distance between a first edge of the lateral surface and the patterned layer is different from a second distance between a second edge of the lateral surface and the patterned layer.

6. The electronic device of claim 1, wherein the lateral surface is slanted with respect to the backside surface of the power die.

7. The electronic device of claim 1, wherein a lateral surface of the patterned layer is non-parallel to a lateral surface of the power die.

8. The electronic device of claim 3, further comprising:
a carrier comprising a first portion electrically connected to the drain region through the patterned layer and a second portion adjacent to the first portion and electrically connected to the source region.

9. The electronic device of claim 8, further comprising:
a conductive element outside the power die and connecting the source region and the second portion.

10. The electronic device of claim 8, wherein the lateral surface of the power die and the carrier define a recess.

11. The electronic device of claim 8, further comprising:
an electrical connector electrically connecting the patterned layer and the first portion of the carrier, wherein a portion of the electrical connector is in contact with a lateral surface of the patterned layer.

12. A electronic device, comprising:
a carrier having a front surface, a backside surface opposite to the front surface, wherein the carrier comprises a plurality of unit dies; and
a plurality of patterned conductive structures disposed on the backside surface of the carrier and spaced apart from each other.

13. The electronic device of claim 12, wherein each of the plurality of unit dies overlaps one of the plurality of patterned conductive structures, respectively.

14. The electronic device of claim 12, wherein each of the plurality of unit dies has a width greater than that of one of the plurality of patterned conductive structures.

15. The electronic device of claim 12, wherein each of the plurality of patterned conductive structures is connected to a drain region of a corresponding one of the plurality of unit dies.

16. The electronic device of claim 12, wherein the carrier comprises silicon carbide.

17. A method of manufacturing an electronic device, comprising:
providing a carrier having a plurality of unit dies and a surface exposing a plurality of drain regions of the plurality of unit dies; and
forming a patterned conductive structure on the plurality of drain regions of the plurality of unit dies to expose a portion of the surface of the carrier.

18. The method of claim 17, further comprising:
separating the plurality of unit dies of the carrier without removing the patterned conductive structure.

19. The method of claim 17, further comprising:
forming a mask on a portion, distinct from the plurality of unit dies, of the surface of the carrier.

20. The method of claim 19, further comprising:
removing the mask after forming the patterned conductive structure; and
performing a peeling test on the patterned conductive structure.
